(19) United States
(12) Patent Application Publication
(10) Pub. No.: US 2022/0201841 A1
(43) Pub. Date: Jun. 23, 2022

(54) Power Module, Method for Manufacturing Power Module, Inverter and DC/DC Converter

(71) Applicant: ZF Friedrichshafen AG, Friedrichshafen (DE)

(72) Inventors: Wei Liu, Friedrichshafen (DE); Mitsutoshi Muraoka, Muraoka (DE)

(21) Appl. No.: 17/557,780

(22) Filed: Dec. 21, 2021

(30) Foreign Application Priority Data
Dec. 22, 2020 (DE) 10 2020 216 480.0

(51) Int. Cl. H05K 1/02; H05K 1/18; H05K 1/11; H05K 3/00; H02M 3/00; H02M 7/00

(52) U.S. Cl. CPC H05K 1/0216; H05K 1/185; H05K 1/115; H05K 2203/1305; H02M 3/003; H02M 7/003; H05K 2201/10287; H05K 3/0014

(57) ABSTRACT

A power module includes: a carrier with a surface; a plurality of power elements and a plurality of external connectors provided on the carrier; a grounded shielding member positioned above the power elements for shielding the electro-magnetic interference of the power elements; an encapsulation layer covering the carrier, the power elements, the shielding member and at least part of the external connectors. A method for manufacturing a power module and an inverter is also provided.

### FIELD OF THE INVENTION

The invention relates generally to a power module with an inner shielding member and a method for manufacturing the power module and an inverter including the power module.

### CROSS-REFERENCE TO RELATED APPLICATION

The present application is related and has right of priority to German Patent Application No. 102020216480.0 filed in the German Patent Office on Dec. 22, 2020, which is incorporated by reference in its entirety for all purposes.

### BACKGROUND OF THE INVENTION

An inverter is usually used to convert direct current (‘DC’) to alternating current (‘AC’) to power a three-phase load, such as an electric motor. Referring to FIG. 1 and FIG. 2, the inverter contains a power module 1 including power elements 12, such as IGBTs, MOSFETs and SiC devices and a drive board 2 driving the power elements 12. Specifically, the power module 1 includes a carrier 11 for carrying power elements 12 and pins or terminals 13, the carrier 11 can be a part of a DBC (direct bonded copper) or an IMS (insulated metal substrate). Resin 14 having low dielectric constant and low stress can be used to encapsulate the power module. The drive board 2 includes a circuit board 20 with electronic components 21,22 (such as, driving chips, resistances, capacitors, diodes, triodes, etc.) on both sides. The pins transmit driving signals for switching on and off the power elements 12 and sensor signals, such as sensor signal for detecting the temperature. And the terminals are connectors, like AC connectors and DC connectors coupled to other electric components. In the conventional design, the power module and the drive board 2 are spaced apart by a relatively large distance H which leads larger inductance of gate loop. Consequently, a non-negligible noise is caused by the inductance of gate loop.

To reduce the inductance of gate loop, the drive board 2 should be closer to the power module 1. However, the power module 1 will interfere the drive board 2 as the drive board 2 becomes closer to the power module 1 and leads malfunction of the power elements, namely an EMC (Electro Magnetic Compatibility) problem occurs.

Inserting an electrical shielding member 3 (like a copper sheet) between the power module 1 and the drive board 2 can somehow improve the EMC problem. In order to avoid a short circuit, there must be a space between the power module and the drive board since chips 22 are provided on the rear surface of the circuit board 20. However, the space between the power module and drive board causes the large inductance of the gate loop, the noise problem is still not fixed.

### BRIEF SUMMARY

In order to balance the noise problem and the EMC problem, example aspects of the present invention provide a power module with an inner shielding member. The power module includes a carrier (for example, being a part of a DBC or an IMS) including a surface, a plurality of power elements and a plurality of external connectors provided on the surface of the surface, a grounded shielding member above the power elements for shielding the electromagnetic interference of the power elements, an encapsulation layer covering the surface of the carrier, the power elements, the shielding member and at least part of the external connectors. In this example design, by encapsulating the shielding member inside the resin made encapsulation layer, electro-magnetic interference of the power elements is shielded effectively.

In a preferred example embodiment, the power module further includes at least one grounding member for electrically connecting the shielding member to the ground.

In another preferred example embodiment, the shielding member is provided with at least one first through hole, the grounding member is a bolt or a screw, and the shielding member is grounded by the bolt or the screw via the first through hole.

In another preferred example embodiment, no bolt or screw is needed, and the shielding member is grounded directly by a bond wire.

In another preferred example embodiment, the power module further includes at least one supporting member for supporting the shielding member inside the encapsulation layer.

In another preferred example embodiment, the shielding member is grounded via the supporting member.

In another preferred example embodiment, the shielding member includes second through holes for the external connectors to pass through.

In another preferred example embodiment, the shielding member is a copper sheet or an aluminum sheet.

In another preferred example embodiment, the shielding member is a shielding cap with a roof covering the power elements and a wall extending perpendicular to the roof.

In another preferred example embodiment, the wall is provided with at least one third through hole for filling material to pass through.

In another preferred example embodiment, the carrier includes a flat plate shape or a Pin-Fin shape.

According to another example aspect of the invention, a method for manufacturing the power module is also disclosed. The method includes: placing a carrier in a cavity of a mold, the carrier (for example, being a part of a DBC or an IMS) including a surface and a plurality of power elements and a plurality of external connectors provided on the surface of the carrier; injecting resin into the cavity to cover the surface of the carrier, the power elements and at least part of each external connector and forming a first encapsulation layer after the resin is solidified; providing a shielding member for shielding the electromagnetic interference of the power elements on the first encapsulation layer; injecting resin into the cavity to cover the shielding member and forming a second encapsulation layer after the resin is solidified; and removing the mold and grounding the shielding member.

In another preferred example embodiment, grounding the shielding member by a bolt or a screw via a first through hole on the shielding member. In another preferred example embodiment, grounding the shielding member by a bond wire directly.

According to another example aspect of the invention, another method for manufacturing the power module is also disclosed. The method includes: placing a carrier in a cavity of a mold, the carrier (for example, being a part of a DBC or an IMS) including a surface, wherein a plurality of power elements and a plurality of external connectors are provided on the surface of the carrier; placing a shielding member for shielding the electromagnetic interference of the power elements above the power elements, wherein the shielding member is supported by at least one supporting member and grounded by at least one grounding member; injecting resin into the cavity to cover the surface of the carrier, the power elements, the shielding member and at least part of each of the external connectors and forming an encapsulation layer after the resin is solidified; and removing the mold.

In another preferred example embodiment, the at least one grounding member is integrated with the at least one supporting member.

In another preferred example embodiment, the shielding member includes second through holes for the external connectors to pass through.

According to another example aspect of the invention, another method for manufacturing the power module is also disclosed. The method includes: placing a carrier in a cavity of a mold, the carrier (for example, being a part of a DBC or an IMS) including a surface, wherein a plurality of power elements and a plurality of external connectors are provided on the surface of the carrier; placing a shielding member for shielding the electromagnetic interference of the power elements on the surface of the carrier, wherein the shielding member is a shielding cap with a roof covering the power elements and a wall extending perpendicular to the roof, the wall is provided with at least one third through hole for filling material to pass through; injecting resin into the cavity to cover the surface of the carrier, the power elements, the shielding member and at least part of each of the external connectors and forming an encapsulation layer after the resin is solidified; and removing the mold.

In another preferred example embodiment, the shielding member includes second through holes for the external connectors to pass through.

According to another example aspect of the invention, an inverter includes a power module as described above and a drive board placed on the power module. Besides, the power module can also be applied in DC/DC converter and power applications.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by on skilled in the art without departing from the spirit and scope of the described embodiments.

FIG. 1 illustrates a cross sectional view of a conventional inverter including a power module and a drive board.

FIG. 2 illustrates a cross sectional view of another conventional inverter with a shielding member.

FIG. 3 is a cross-sectional structural diagram illustrating a step of placing a carrier with a DBC, power elements and external connectors in a lower mold in accordance with the first example embodiment of the invention.

FIG. 4 is a cross-sectional structural diagram illustrating steps of forming a first encapsulation layer on the structure shown in FIG. 3.

FIG. 5 is a cross-sectional structural diagram illustrating steps of placing a shielding member and a plug on the structure shown in FIG. 4.

FIG. 6 is a cross-sectional structural diagram illustrating steps of forming a second encapsulation layer on the structure shown in FIG. 5.

FIG. 7 is a cross-sectional structural diagram illustrating a power module after the mold is removed.

FIG. 8 illustrates a cross sectional view of an inverter including a power module with an inner shielding member and a drive board.

FIG. 9 illustrates a cross sectional view of an inverter including a power module with an inner shielding member and a drive board in accordance with the second example embodiment of the invention.

FIG. 10 illustrates a top view of a shielding member in accordance with the third example embodiment of the invention.

FIG. 11 is a cross-sectional structural diagram illustrating steps of placing a shielding member and a plug on the first encapsulation layer in accordance with the third example embodiment of the invention.

FIG. 12 is a cross-sectional structural diagram illustrating a power module after the mold is removed in accordance with the third example embodiment of the invention.

FIG. 13 is a cross-sectional structural diagram illustrating steps of placing a shielding member in accordance with the fourth example embodiment of the invention.

FIG. 14 is a cross-sectional structural diagram illustrating a power module after the mold is removed in accordance with the fourth example embodiment of the invention.

FIG. 15 illustrates a perspective view of a shielding member in accordance with the fifth example embodiment of the invention.

FIG. 16 illustrates another perspective view of a shielding member in accordance with the fifth example embodiment of the invention.

FIG. 17 is a cross-sectional structural diagram illustrating steps of placing a shielding member in accordance with the fifth example embodiment of the invention.

FIG. 18 is a cross-sectional structural diagram illustrating a power module after the mold is removed in accordance with the fifth example embodiment of the invention.

FIG. 19 is a cross-sectional structural diagram illustrating steps of placing a shielding member on the first encapsulation layer in an exploded view in accordance with the sixth example embodiment of the invention.

FIG. 20 is a cross-sectional structural diagram illustrating a power module after the mold is removed in accordance with the sixth example embodiment of the invention.

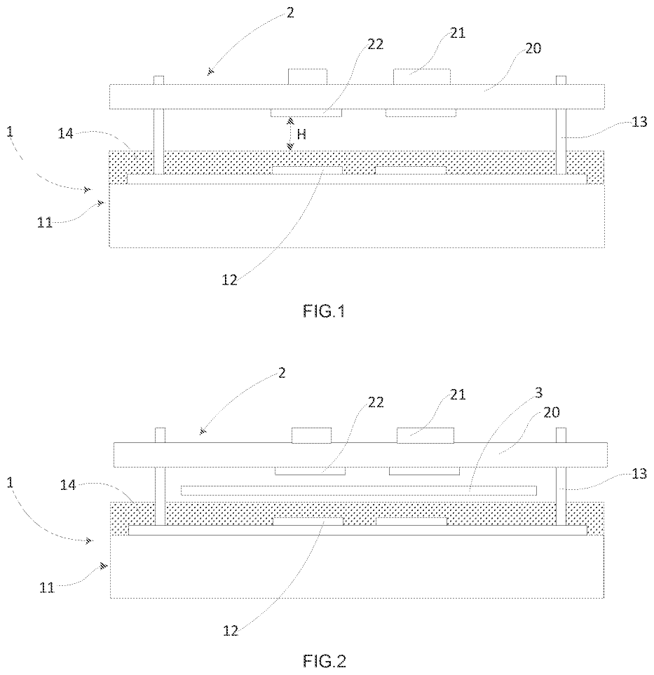

### DETAILED DESCRIPTION OF THE EMBODIMENTS

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

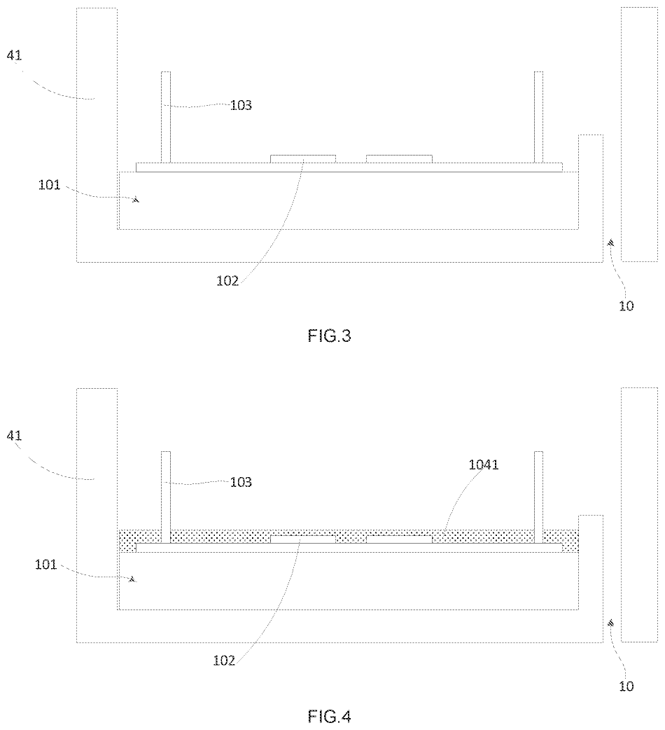

Referring now to the drawings, example embodiments of the invention are described in detail. A power module with an inner shielding member, a method for manufacturing the power module and an inverter with the power module of the first example embodiment are described in detail with reference to FIG. 3-FIG. 9. Referring to FIG. 7 and FIG. 8, the power module 10 includes a carrier 101 including a surface (for example, a front surface), a plurality of power elements 102 and a plurality of external connectors 103 provided on the surface of the carrier 101. In this case, the carrier is a part of a DBC or an IMS. The power module further includes a grounded shielding member 30 above the power elements 102 for shielding the electro-magnetic interference of the power elements 102, an encapsulation layer 104 covering the surface of the carrier 101, the power elements 102, the shielding member 30 and at least part of the external connectors 103. More details are disclosed in the following description with reference to the method for manufacturing the power module.

Referring to FIG. 3-FIG. 8, the power module 10 is manufactured by the following processes. Firstly, a carrier 101 and a plurality of power elements 102, such as IGBTs or SiC devices on the front surface of the carrier 101 are provided. By switching on and off the power elements, direct current can be converted to alternating current. A plurality of external connectors 103, such as AC connectors, DC connectors and pins are also provided on the front surface of the carrier 101. The AC connectors are coupled to an AC component, such as an electric motor, while the DC connectors are coupled to a DC power. Pins transmit driving signals for switching on and off the power elements 102 and sensor signals, such as sensor signals for detecting the temperature voltage and current.

In FIG. 3, the carrier 101 with the power elements 102 and the external connectors 103 is placed on the inner bottom surface of a lower mold 41 with an injecting hole 10. An upper mold (not shown) will be assembled with the lower mold 41 to form a cavity. Then resin is injected into the cavity via the injecting hole 10 to cover the carrier 101, the power elements 102 and at least part of each external connector 103. After the resin is solidified, a first encapsulation layer 1041 is formed, as shown in FIG. 4.

Referring now to FIG. 5, a shielding member 30 for shielding the electromagnetic interference of the power elements 102 is placed on the first encapsulation layer 1041. The shielding member 30 is a copper sheet covering the power elements 102 such that the electromagnetic interference of the power elements 102 is sheltered by the shielding member 30. Meanwhile, a plug 6 is placed on the shielding member 30 to prevent the following resin injection.

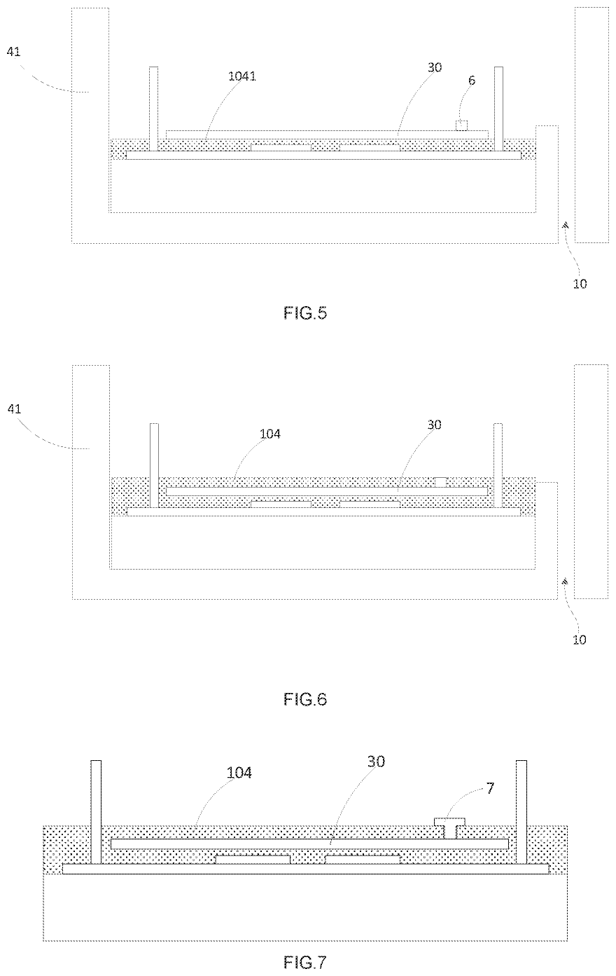

In FIG. 6, resin is injected into the cavity via the injecting hole 10 to cover the shielding member 30 and another part of the external connectors 103. A second encapsulation layer is formed after the resin is solidified. The first encapsulation layer and the second encapsulation layer together are herein referred to as the encapsulation layer 104. The top of the encapsulation layer 104 shall not go beyond the top of the plug 6. And then the molds (both upper mold and the lower mold 41) are removed. Referring now to FIG. 7, the plug 6 is removed and a bolt 7 is inserted into the encapsulation layer to ground the shielding member 30 (forming a first through hole when inserting the bolt 7). Via the bolt 7, the shielding member 30 is electrically coupled to the ground, for example, of a cooling system for cooling the power module.

Referring now to FIG. 8, an inverter including the power module 10 (the bolt is not shown) manufactured by the above-mentioned method and a drive board 20 is shown. The drive board 20 includes a circuit board 200, chips 201 on the front surface of the circuit board 200 and chips 202 on the rear surface of the circuit board 200. The drive board 20 is coupled to the power module 10 by the external connectors 103. Driving signals for switching on and off the power elements 102 and sensor signals for detecting characteristic parameters of the power module 10 are transmitted by the external connectors 103. In this example embodiment, the drive board 20 can be placed as close to the power module 10 as possible as the shielding member 30 is encapsulated inside the encapsulation layer 104. Referring to FIG. 9, in the second example embodiment, the drive board 20 can even be placed on the top surface of the power module 10 in order to make the inverter more compact. In FIG. 9, the chips 202 provided on the rear surface of the drive board 20 are in contact with the top surface of the resin-made encapsulation layer 104, with no fear of short circuit.

In this example inner shielding member design, by providing the drive board 20 as close to the power module as possible, the inductance of gate loop is reduced significantly. Thus, the noise caused by the inductance of gate loop is negligible. Meanwhile, by the shielding member 30 inside the encapsulation layer 104, the EMC problem is well contained even if the drive board 20 is very close to the power module 10. Therefore, the contradiction between the noise problem and the EMC problem is compromised.

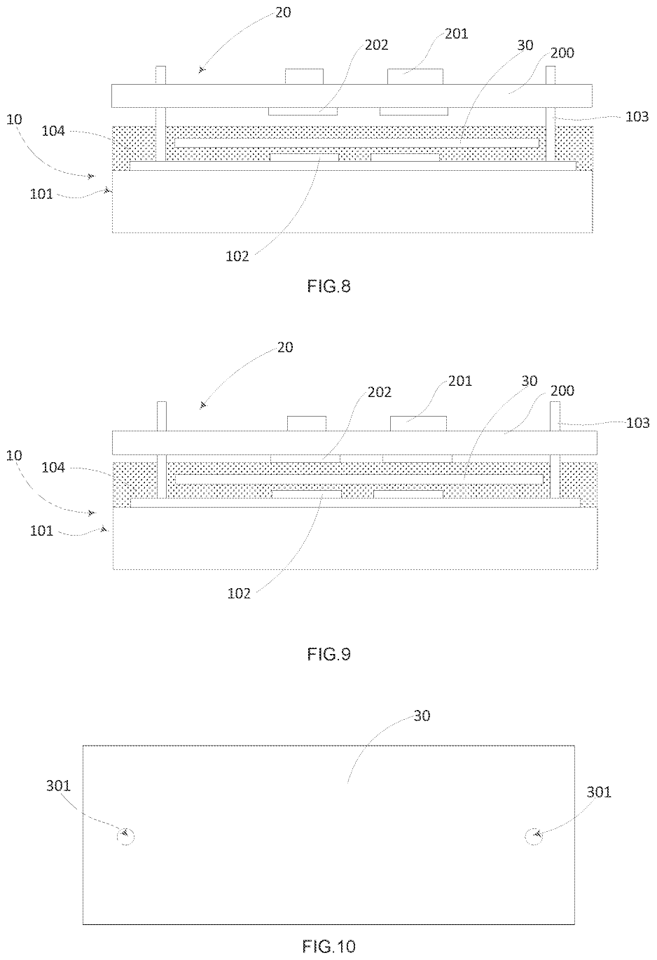

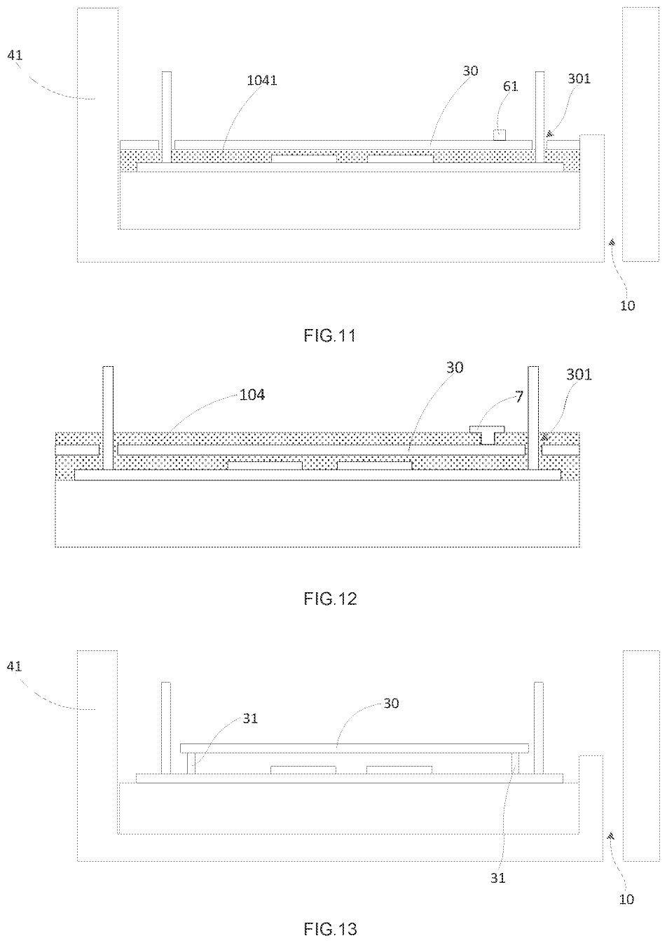

In the third example embodiment, the shielding member 30 having the same dimension (length and width) as the carrier, as shown in FIG. 10, is used. The shielding member 30 includes second through holes 301 for the external connectors 103 to pass through. In this example embodiment, the entire carrier region is covered by the shielding member 30 and the electro-magnetic interference from the power elements 102 is well shielded. The manufacturing method of the power module in this example embodiment is similar to that of the above-mentioned example embodiment. Referring to FIG. 4, FIG. 11 and FIG. 12, after forming the first encapsulation layer 1041, the shielding member 30 shown in FIG. 10 is placed on the first encapsulation layer 1041 with the external connectors 103 passing through the second through holes 301, and meanwhile a plug 61 is placed on the shielding member. The following processes are just the same as that of the above-mentioned example embodiment, the shielding member 30 is grounded by a bolt or a screw 7.

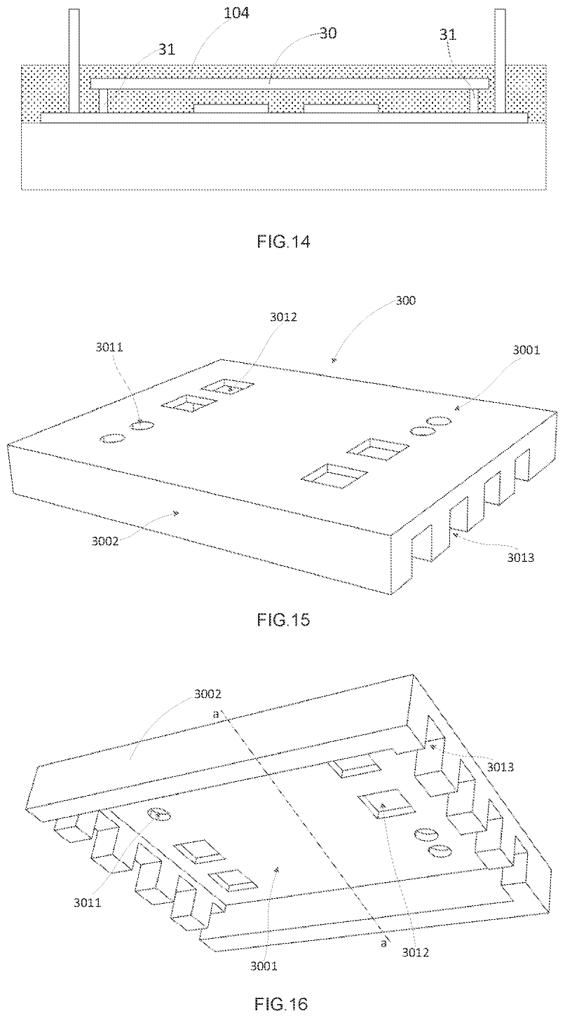

Referring now to FIG. 3, FIG. 13 and FIG. 14, the fourth example embodiment of the power module and the manufacturing method of making the same are illustrated. In this example embodiment, by supporting the shielding member with supporting members 31, only one injecting process is needed. As shown in FIG. 13, supporting members 31 are provided to support the shielding member 30 on the DBC. The shielding member 30 is grounded via at least one of the supporting members 31. Namely, at least one supporting member 31 is also used as a grounding member. Alternatively, the power module may include four conductive columns on four corners of the shielding member for supporting the shielding member, each conductive column grounding the shielding member to the ground, such as, the ground of the cooling system of the power module. After the shielding member is supported on the supporting members, resin is injected into the cavity formed by an upper mold and a lower mold 41, the encapsulation layer 104 is formed after resin is solidified after which the molds are removed. The power module with an inner shielding member is shown in FIG. 14.

Referring now to FIG. 15-FIG. 18, the fifth example embodiment in which a shielding member 300 with a different shape is disclosed. The shielding member is a shielding cap 300 with a roof 3001 covering the power elements and a wall 3002 extending perpendicular to the roof. In the roof 3001, a plurality of second through holes 3011 and 3012 are provided for pins (transmitting sensor signals) and terminals (AC connectors and DC connectors) to pass through. In the wall 3002, a plurality of third through holes 3013 are provided for filling material to pass through. In this example embodiment, the filling material is resin.

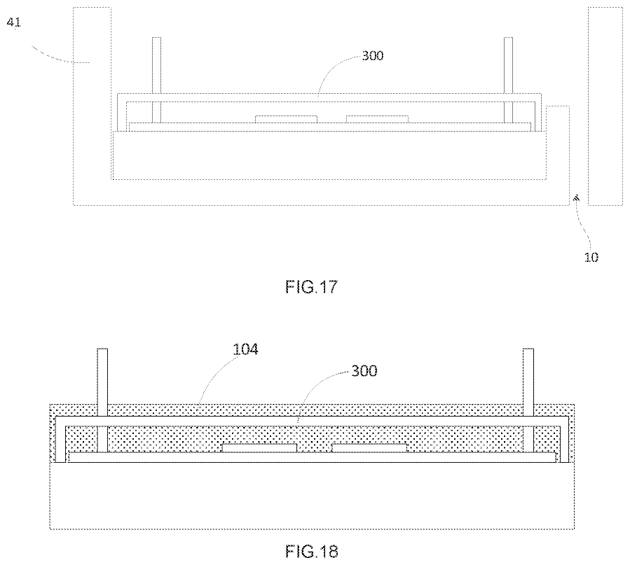

The manufacturing method of the power module in this example embodiment is similar to that in which a cooper sheet is used as the shielding member. As shown in FIG. 17, the shielding cap 300 is placed on the carrier to cover the front surface of the carrier and the power elements thereon, and then resin is injected to form the encapsulation layer 104. The power module with an inner shielding cap 300 is shown in FIG. 18. By providing a drive board on the power module as shown in FIG. 18, a compact inverter with excellent electro-magnetic compatibility is formed since the shielding cap 300 shields electro-magnetic interference of the power elements in all directions.

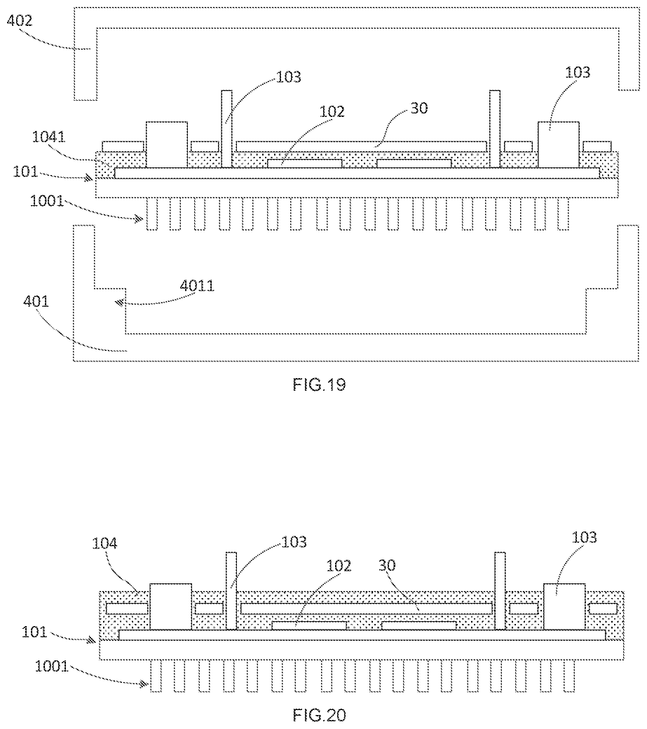

In the preceding example embodiments, the carrier of the power module has a flat shape. From the standpoint of thermal effect, a carrier having a Pin-Fin shape is more ideal. The sixth example embodiment including a carrier having a Pin-Fin shape will be described further below with reference to FIG. 19 and FIG. 20. FIG. 19 illustrates a cross sectional and exploded view of a power module with a Pin-Fin shape provided in a mold (formed by an upper mold 402 and a lower mold 401) before the second resin injection. The carrier 101 has a Pin-Fin shape 1001 on the rear surface of the carrier 101 in order to dissipate heat rapidly. By providing a step 4011 in the inner bottom surface of the lower mold 401, the carrier 101 can be placed steadily in the lower mold during resin injection process. After the first encapsulation layer 1041 is formed, a shielding member 30 with several second through holes is placed on the first encapsulation layer 1041. The second through holes allow external connectors 103 (pins and terminals) to pass through, followed by the second resin injection process and the encapsulation layer 104 is formed after the solidification of resin. A power module with a Pin-Fin shape shown in FIG. 20 is formed after removing the mold (grounding member not shown).

A number of alternative structural elements and processing steps have been suggested for the preferred embodiment. Thus while the invention has been described with reference to specific embodiments, the description is illustrative of the invention and is not to be construed as limiting the invention. Various modifications and applications may occur to those skilled in the art without departing from the true spirit and scope of the invention as defined by the appended claims.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

1-20: (canceled)

21. A power module, comprising:
a carrier with a surface;
a plurality of power elements and a plurality of external connectors provided on the surface of the carrier;
a grounded shielding member positioned above the power elements and configured for shielding electromagnetic interference of the power elements; and
an encapsulation layer covering the surface of the carrier, the power elements, the shielding member and at least part of the external connectors.

22. The power module of claim 21, wherein the power module further comprises at least one grounding member for electrically connecting the shielding member to a ground.

23. The power module of claim 22, wherein the shielding member defines at least one first through-hole, the grounding member comprises a bolt or a screw, and the shielding member is grounded by the bolt or the screw extending through the first through-hole.

24. The power module of claim 21, wherein the shielding member is grounded by a bond wire.

25. The power module of claim 21, wherein the power module further comprises at least one supporting member for supporting the shielding member inside the encapsulation layer.

26. The power module of claim 25, wherein the shielding member is grounded via the supporting member.

27. The power module of claim 21, wherein the shielding member defines second through-holes for the external connectors to pass through.

28. The power module of claim 21, wherein the shielding member comprises a copper sheet or an aluminum sheet.

29. The power module of claim 21, wherein the shielding member comprises a shielding cap with a roof covering the power elements and a wall extending perpendicular to the roof.

30. The power module of claim 29, wherein the wall is provided with at least one third through-hole for filling material to pass through.

31. The power module of claim 21, wherein the carrier includes a flat plate shape or a Pin-Fin shape.

32. A method for manufacturing a power module, comprising:
placing a carrier in a cavity of a mold, the carrier including a surface, wherein a plurality of power elements and a plurality of external connectors are provided on the surface of the carrier;
injecting resin into the cavity to cover the surface of carrier, the power elements, and at least part of each of the external connectors in order to form a first encapsulation layer after the resin is solidified;
providing a shielding member for shielding electromagnetic interference of the power elements on the first encapsulation layer;
injecting resin into the cavity to cover the shielding member and form a second encapsulation layer after the resin is solidified; and
removing the mold and grounding the shielding member.

33. The method as claimed in claim 32, wherein grounding the shielding member comprises:
grounding the shielding member by extending a bolt or a screw through a first through-hole on the shielding member; or
grounding the shielding member by a bond wire.

34. A method for manufacturing a power module, comprising:
placing a carrier in a cavity of a mold, the carrier including a surface, wherein a plurality of power elements and a plurality of external connectors are provided on the surface of the carrier;
placing a shielding member above the power elements for shielding electromagnetic interference of the power elements, wherein the shielding member is supported by at least one supporting member and is grounded by at least one grounding member;
injecting resin into the cavity to cover the surface of the carrier, the power elements, the shielding member, and at least part of each of the external connectors in order to form an encapsulation layer after the resin is solidified;
removing the mold.

35. The method of claim 34, wherein the at least one grounding member is integrated with the at least one supporting member.

36. The method of claim 35, wherein the shielding member defines second through holes for the external connectors to pass through.

37. A method for manufacturing a power module, comprising:
placing a carrier in a cavity of a mold, the carrier including a surface, wherein a plurality of power elements and a plurality of external connectors provided on the surface of the carrier;
placing a shielding member for shielding electromagnetic interference of the power elements on the surface of the carrier, wherein the shielding member is a shielding cap with a roof covering the power elements and a wall extending perpendicular to the roof, and the wall is provided with at least one third through-hole for filling material to pass through;
injecting resin into the cavity to cover the surface of the carrier, the power elements, the shielding member, and at least part of each of the external connectors in order to form an encapsulation layer after the resin is solidified; and
removing the mold.

38. The method of claim 37, wherein the shielding member defines second through-holes for the external connectors to pass through.

39. An inverter, comprising:
the power module of claim 21; and
an inverter drive board placed on the power module.

40. A DC/DC converter, comprising:
the power module of claim 21; and
a DC/DC converter drive board placed on the power module.
